(19) United States
(12) Patent Application Publication
(10) Pub. No.: US 2025/0017063 A1
(43) Pub. Date: Jan. 9, 2025

(54) DISPLAY DEVICE

(71) Applicant: Samsung Display Co., Ltd., Yongin-si (KR)

(72) Inventor: Jong Hyun CHOI, Yongin-si (KR)

(21) Appl. No.: 18/610,056

(22) Filed: Mar. 19, 2024

(30) Foreign Application Priority Data
Jul. 4, 2023 (KR) 10-2023-0086320

(51) Int. Cl. H10K 59/131; G09G 3/3233

(52) U.S. Cl. CPC H10K 59/131; G09G 3/3233; G09G 2300/0408

(57) ABSTRACT

A display device includes: display pixels formed in an image display area of a display panel; a gate driving circuit formed in the image display area and configured to supply gate signals to the display pixels; a display driving circuit configured to supply a data voltage to data lines in the image display area through fan-out lines arranged in a non-display area of the display panel and configured to supply gate control signals to the gate driving circuit through gate control lines arranged in the non-display area; and driving voltage lines arranged in the non-display area and configured to to supply driving voltages to the gate driving circuit, wherein at least one gate control line of the gate control lines intersects one or more fan-out lines of the fan-out lines in one side direction of the image display area corresponding to an arrangement direction of the display driving circuit.

### CROSS-REFERENCE TO RELATED APPLICATION

The present application claims priority to and the benefit of Korean Patent Application No. 10-2023-0086320, filed on Jul. 4, 2023, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

As an information society develops, consumer demand for display devices for displaying images is increasing in various forms. For example, display devices are applied to various electronic devices such as smartphones, digital cameras, laptop computers, navigation devices, and smart televisions.

The display device may be a flat panel display device such as a liquid crystal display device, a field emission display device, or an organic light emitting display device. Among flat panel display devices, the light emitting display device may include a light emitting element in which each of the pixels of a display panel may emit light by itself, thereby displaying images without a backlight unit or the like.

Display devices may include a display area and a non-display area around the display area. Pixel circuits for displaying images may be located in the display area. On the other hand, various driving circuits for driving the pixel circuits may be located in the non-display area corresponding to a dead space of the display device. Recently, a display device having a relatively wider display surface in a limited size may be desired. To this end, methods for minimizing or reducing bezel areas including the dead space may be desired.

However, in mobile display devices such as smartphones and tablet PCs compared to large screen display devices such as monitors, because the driving circuit and various lines are intensively arranged in one narrow side direction, there may be limits to reducing the dead space.

The above information disclosed in this Background section is only for enhancement of understanding of the background and therefore the information discussed in this Background section does not necessarily constitute prior art.

### SUMMARY

Aspects of some embodiments of the present disclosure include a line arrangement structure that may be capable of reducing a dead space of a display panel used in a mobile display device such as a smartphone or a tablet PC.

Aspects of some embodiments of the present disclosure may also include a display device capable of preventing or reducing an occurrence of electromagnetic coupling between lines overlapping or intersecting each other.

However, aspects of embodiments according to the present disclosure are not restricted to those set forth herein. The above and other aspects of the present disclosure will become more apparent to one of ordinary skill in the art to which the present disclosure pertains by referencing the detailed description of the present disclosure given below.

According to some embodiments of the disclosure, a display device comprising display pixels formed in an image display area of a display panel, a gate driving circuit formed in the image display area to supply gate signals to the display pixels, a display driving circuit supplying a data voltage to data lines in the image display area through fan-out lines arranged in a non-display area of the display panel and supplying gate control signals to the gate driving circuit through gate control lines arranged in the non-display area, and driving voltage lines arranged in the non-display area to supply driving voltages to the gate driving circuit, wherein at least one gate control line of the gate control lines intersects one or more fan-out lines of the fan-out lines in one side direction of the image display area corresponding to an arrangement direction of the display driving circuit.

According to some embodiments of the disclosure, a display device comprising a display panel including an image display area and a non-display area, display pixels formed in the image display area, a gate driving circuit formed in the image display area to supply gate signals to the display pixels, a display driving circuit supplying a data voltage to data lines in the image display area through fan-out lines arranged in the non-display area and supplying gate control signals to the gate driving circuit through gate control lines arranged in the non-display area, and driving voltage lines arranged in the non-display area to supply driving voltages to the gate driving circuit, wherein at least one gate control line of the gate control lines intersects one or more fan-out lines of the fan-out lines in one side direction of the image display area corresponding to an arrangement direction of the display driving circuit, and at least one driving voltage line of the driving voltage lines intersects one or more fan-out lines of the fan-out lines in one side direction of the image display area corresponding to an arrangement direction of the display driving circuit.

According to some embodiments, the at least one gate control line of the gate control lines intersect one or more data lines of the data lines in the image display area in one side direction corresponding to the arrangement direction of the display driving circuit.

According to some embodiments, the gate control lines include a gate start signal transmission line and a plurality of clock signal transmission lines, and one or more signal transmission lines of the gate start signal transmission line and the plurality of clock signal transmission lines intersect the one or more data lines or intersect the one or more fan-out lines.

In a display device according to some embodiments of the present disclosure, a dead space caused by the embedded circuits may be reduced by forming an embedded circuit of a display panel applied to a mobile display device, for example, a gate driving circuit (or a scan driving circuit) in the display area.

Further, by improving the arrangement structure of lines overlapping or intersecting each other, the occurrence of electromagnetic coupling between the lines overlapping or intersecting each other may be prevented or reduced and reliability may be relatively improved.

However, the characteristics of embodiments according to the present disclosure are not restricted to those specifically described herein. The above and other characteristics of embodiments according to the present disclosure will become more apparent to one of ordinary skill in the art to which the embodiments pertain by referencing the claims and their equivalents.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view illustrating a display device according to some embodiments;

FIG. 2 is a plan view illustrating the display device according to some embodiments;

FIG. 3 is a side view illustrating the display device according to some embodiments;

FIG. 4 is a layout view schematically illustrating a display panel as illustrated in FIGS. 1 to 3 according to some embodiments;

FIG. 5 is a layout view illustrating an enlarged AA area in which data lines, gate control lines, and power lines of FIG. 4 intersect according to some embodiments;

FIG. 6 is a layout view specifically illustrating an image display area illustrated in FIG. 5 according to some embodiments;

FIG. 7 is an view illustrating a gate driving circuit formed in the image display area of FIGS. 4 to 6 divided for each block according to some embodiments;

FIG. 8 is a layout view illustrating a more enlarged intersection area of the data lines, the gate control lines, and the power lines of FIG. 5 according to some embodiments;

FIG. 9 is a layout view specifically illustrating a BB area in which the data lines of FIG. 8 and one gate control line intersect according to some embodiments;

FIG. 10 is a cross-sectional view illustrating a section taken along line C-C′ illustrated in FIG. 9 according to some embodiments;

FIG. 11 is a layout view schematically illustrating a display panel structure as illustrated in FIGS. 1 to 3 according to some embodiments;

FIG. 12 is a layout view illustrating an enlarged EE area in which data lines, gate control lines, and power lines of FIG. 11 intersect according to some embodiments;

FIG. 13 is a layout view specifically illustrating an EE area in which the data lines of FIG. 12 and one gate control line intersect according to some embodiments;

FIG. 14 is a cross-sectional view illustrating a section taken along line F-F′ illustrated in FIG. 13 according to some embodiments;

FIGS. 15 and 16 are perspective views illustrating a display device according to some embodiments of the present disclosure; and

FIGS. 17 and 18 are perspective views illustrating a display device according to some embodiments of the present disclosure.

### DETAILED DESCRIPTION

Aspects of some embodiments of the present disclosure will now be described more fully hereinafter with reference to the accompanying drawings, in which aspects of some embodiments of the disclosure are shown. This disclosure may, however, be embodied in different forms and should not be construed as limited to the embodiments set forth herein. Rather, these embodiments are provided so that this disclosure will be thorough and complete, and will filly convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, aspects of some embodiments will be described in more detail with reference to the accompanying drawings.

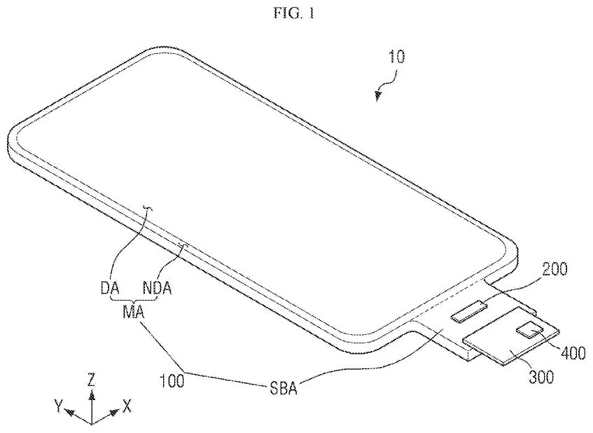

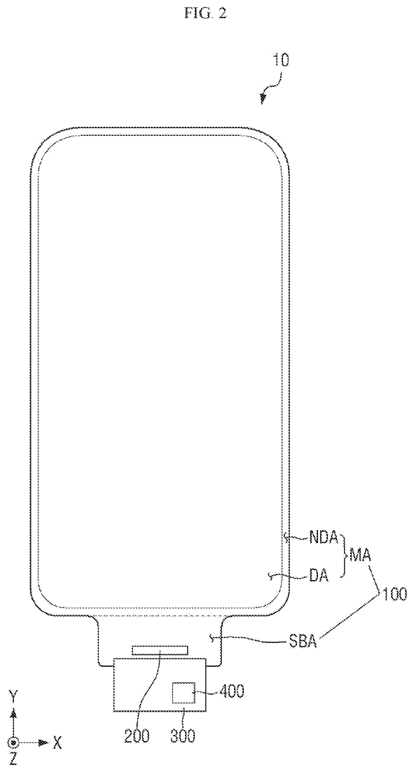

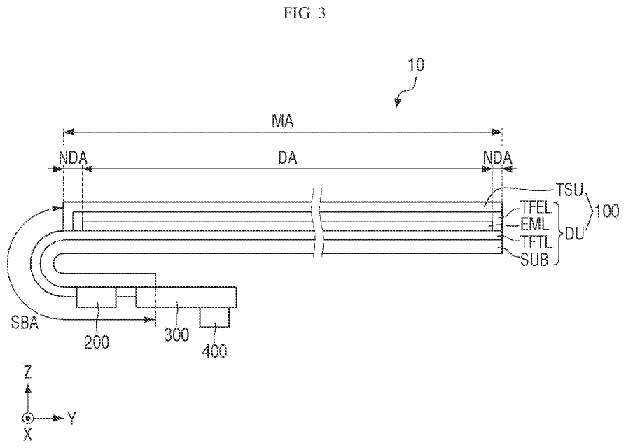

FIG. 1 is a perspective view illustrating a display device according to some embodiments. In addition, FIG. 2 is a plan view illustrating the display device according to some embodiments, and FIG. 3 is a side view illustrating the display device according to some embodiments.

Referring to FIGS. 1 to 3, a display device 10 according to some embodiments may be applied to portable electronic devices such as a mobile phone, a smartphone, a tablet personal computer (PC), a mobile communication terminal, an electronic notebook, an electronic book, a portable multimedia player (PMP), navigation, and an ultra mobile PC (UMPC). Alternatively, the display device 10 according to some embodiments may be applied as a display unit of a television, a laptop computer, a monitor, a billboard, or the Internet of Things (IOT). Alternatively, the display device 10 according to some embodiments may be applied to wearable devices such as a smart watch, a watch phone, a glasses-type display, and a head mounted display (HMD). Alternatively, the display device 10 according to some embodiments may be applied to an instrument panel of a vehicle, a center fascia of a vehicle, a center information display (CID) located on a dashboard of a vehicle, a room mirror display substituting for a side mirror of a vehicle, or a display located on a rear surface of a front seat as entertainment for a rear seat of a vehicle.

The display device 10 according to some embodiments may be a light emitting display device such as an organic light emitting display device using an organic light emitting diode, a quantum dot light emitting display device including a quantum dot light emitting layer, an inorganic light emitting display device including an inorganic semiconductor, and a micro light emitting display device using a micro or nano light emitting diode (LED). Hereinafter, it is mainly described that the display device 10 according to some embodiments is the organic light emitting display device, but the application range is not limited thereto.

The display device 10 according to some embodiments includes a display panel 100, a display driving circuit 200, a circuit board 300, and a touch driving circuit 400.

The display panel 100 may be formed in a rectangular plane having short sides in a first direction (X-axis direction) and long sides in a second direction (Y-axis direction) intersecting the first direction (X-axis direction). Here, a corner where the short side in the first direction (X-axis direction) and the long side in the second direction (Y-axis direction) meet is rounded with a curvature (e.g., a set or predetermined curvature). The planar shape of the display panel 100 is not limited to the quadrangular shape having the rounded corners, and may be other polygonal shapes having the rounded corners, a circular shape, or an elliptical shape. The display panel 100 may be formed to be flat, but embodiments according to the present disclosure are not limited thereto. For example, the display panel 100 includes curved portions that are formed at left and right distal ends and have a constant curvature or a varying curvature. In addition, the display panel 100 may be flexibly formed to be curved, bent, folded, or rolled.

The display panel 100 includes a main area MA and a sub-area SBA.

The main area MA includes a display area DA displaying images and a non-display area NDA which is a peripheral area of the display area DA. The display area DA includes pixels for displaying images. The sub-area SBA may protrude from one side of the main area MA in the second direction (Y-axis direction).

It is illustrated in FIGS. 1 and 2 that the sub-area SBA is unfolded, but the sub-area SBA may be bent as illustrated in FIG. 3, and in this case, the sub-area SBA may be arranged in a rear surface direction of the display panel 100. When the sub-area SBA is bent, the sub-area SBA may overlap the main area MA in a third direction (Z-axis direction), which is a thickness direction of a substrate SUB. The display driving circuit 200 may be located in the sub-area SBA.

Referring to FIG. 3, the display panel 100 includes a display module DU including a substrate SUB, a thin film transistor layer TFTL, a light emitting element layer EML, and an encapsulation layer TFEL, and a touch sensing unit TSU formed on a front surface of the display module DU.

The thin film transistor layer TFTL may be located on the substrate SUB. The thin film transistor layer TFTL may be located in the main area MA and the sub-area SBA. The thin film transistor layer TFTL includes thin film transistors.

The light emitting element layer EML may be located on the thin film transistor layer TFTL. The light emitting element layer EML may be located in the display area DA of the main area MA. The light emitting element layer EML includes light emitting elements located in light emitting portions.

The encapsulation layer TFEL may be located on the light emitting element layer EML. The encapsulation layer TFEL may be located in the display area DA and the non-display area NDA of the main area MA. The encapsulation layer TFEL includes at least one inorganic layer and at least one organic layer for encapsulating the light emitting element layer.

The touch sensing unit TSU may be formed or mounted on the encapsulation layer TFEL. The touch sensing unit TSU may be located on the display area DA of the main area MA. The touch sensing unit TSU may sense a touch of a body part such as a finger or an electronic pen by using touch electrodes.

A cover window for protecting an upper portion of the display panel 100 may be located on the touch sensing unit TSU. The cover window may be attached onto the touch sensing unit TSU by a transparent adhesive member such as an optically clear adhesive (OCA) film or an optically clear resin (OCR). The cover window may also be made of an inorganic material such as glass or also be made of an organic material such as plastic or a polymer material. In order to prevent or reduce deterioration of visibility of an image due to reflection of external light, a polarizing layer may be additionally located between the touch sensing unit TSU and the cover window.

The display driving circuit 200 may generate signals and voltages for driving the display panel 100. The display driving circuit 200 may be formed as an integrated circuit (IC) and may be attached onto the display panel 100 by a chip on glass (COG) method, a chip on plastic (COP) method, or an ultrasonic bonding method, but embodiments according to the present disclosure are not limited thereto. For example, the display driving circuit 200 may be attached onto the circuit board 300 in a chip on film (COF) manner.

The circuit board 300 may be attached to one end of the sub-area SBA formed in the display panel 100. Therefore, the circuit board 300 may be electrically connected to the display panel 100 and the display driving circuit 200. The display panel 100 and the display driving circuit 200 may receive digital video data, timing signals, and driving voltages through the circuit board 300. The circuit board 300 may be a flexible printed circuit board, a printed circuit board, or a flexible film such as a chip on film.

The touch driving circuit 400 may be located on the circuit board 300 instead of the display panel 100. In this case, the touch driving circuit 400 may be formed as an integrated circuit (IC) and attached to the circuit board 300.

The touch driving circuit 400 may be electrically connected to touch electrodes of the touch sensing unit TSU. The touch driving circuit 400 applies touch driving signals to the touch electrodes of the touch sensing unit TSU, and measures an amount of charge change in mutual capacitance of each of touch nodes formed by the touch electrodes. For example, the touch driving circuit 400 measures a change in capacitance of the plurality of touch nodes according to a change in the magnitude of a voltage or the amount of current of a touch sensing signal received through the touch electrodes. In this way, the touch driving circuit 400 may determine whether or not a user's touch is made, whether or not a user's approach is made, and the like, according to the amount of charge change in the mutual capacitance of each of the plurality of touch nodes. The user's touch indicates that a user's finger or an object such as an electronic pen comes into direct contact with one surface of the cover window located on the touch sensing unit TSU. The user's approach indicates that the user's finger or the object such as the electronic pen hovers above one surface of the cover window.

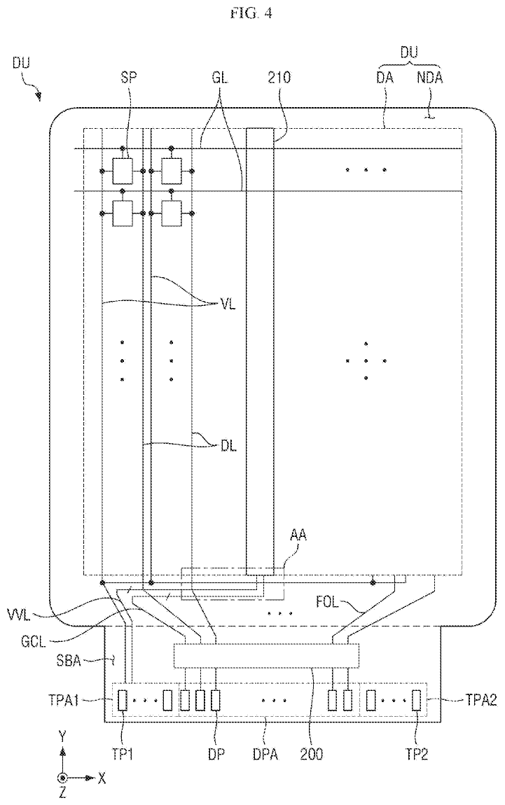

FIG. 4 is a layout view schematically illustrating a display panel structure according to some embodiments as illustrated in FIGS. 1 to 3. For example, FIG. 4 is a layout view illustrating a display area DA and a non-display area NDA of the display module DU before the touch sensing unit TSU is formed.

The display area DA, which is an area configured to display images, may be defined as a central area of the display panel 100. The display area DA may include a plurality of pixels SP, a plurality of gate lines GL, a gate driving circuit 210, a plurality of data lines DL, and a plurality of power lines VL.

The gate driving circuit 210 may be formed and located in the Y-axis direction or the X-axis direction in the display area DA. For example, the gate driving circuit 210 may be formed and located in the Y-axis direction, which is a direction in which the gate lines GL are spaced apart from each other. The gate driving circuit 210 sequentially generates a plurality of gate signals (or scan signals) based on the gate control signal received from the display driving circuit 200, and sequentially supplies the gate signals to the plurality of gate lines GL. In this case, the gate driving circuit 210 may sequentially supply the gate signals to the gate lines GL that are spaced apart from each other in the Y-axis direction and extended in the X-axis direction and arranged in parallel.

In the display area DA where the gate driving circuit 210 is formed, the gate lines GL are arranged in the X-axis direction, and the data lines DL are arranged in the Y-axis direction to intersect the gate lines GL. The plurality of pixels SP are respectively located at intersection areas of the gate lines GL arranged in parallel in the X-axis direction and the data lines DL arranged in parallel in the Y-axis direction. Here, the plurality of pixels SP may be defined as a minimum unit outputting image display light.

The gate driving circuit 210 sequentially generates gate signals in units of at least one frame period based on the gate control signal received through the gate control lines GCL, and supplies the gate signals to the gate lines GL in the order arranged in the Y-axis direction. The plurality of gate lines GL may supply the gate signal applied from the gate driving circuit 210 to the plurality of pixels SP.

The plurality of data lines DL may supply a data voltage received from the display driving circuit 200 to the plurality of pixels SP. The plurality of data lines DL may extend in the Y-axis direction and may be spaced apart from each other in the X-axis direction.

The plurality of power lines VL may supply a power voltage supplied from the display driving circuit 200 or a power supply unit to the plurality of pixels SP. Here, the power voltage may be at least one of a driving voltage, an initialization voltage, or a reference voltage. The plurality of power lines VL may extend in the Y-axis direction and may be spaced apart from each other in the X-axis direction.

The non-display area NDA may be an area surrounding (e.g., in a periphery or outside a footprint of) the display area DA. The non-display area NDA may include fan-out lines FOL, which are extension lines of the data lines DL, gate control lines GCL, and driving voltage lines VVL.

The fan-out lines FOL may extend from the display driving circuit 200 to the data lines DL of the display area DA. Each of the fan-out lines FOL may supply the data voltage received from the display driving circuit 200 to each of the data lines DL.

The gate control lines GCL may extend from the display driving circuit 200 to the gate driving circuit 210 of the display area DA. The gate control lines GCL may supply the gate control signals received from the display driving circuit 200 to the gate driving circuit 210. For example, the gate control lines GCL may include a gate start signal transmission line and a plurality of clock signal transmission lines. A gate start signal from the display driving circuit 200 is supplied to the gate driving circuit 210 through the gate start signal transmission line. In addition, respective clock signals having different phases are supplied to the gate driving circuit 210 through respective clock signal transmission lines.

The driving voltage lines VVL may extend from the display driving circuit 200 or a power supply end of the power supply unit to the gate driving circuit 210 of the display area DA. The driving voltage lines VVL supply high potential and low potential driving voltages supplied from the display driving circuit 200 or the power supply unit to the gate driving circuit 210. For example, the driving voltage lines VVL may include high potential and low potential driving voltage lines. The high potential driving voltage is supplied to the gate driving circuit 210 through the high potential driving voltage line. In addition, the low potential driving voltage is supplied to the gate driving circuit 210 through the low potential driving voltage line.

In the display module DU used in a mobile display device such as a smartphone or tablet PC, because the data lines DL and the gate control lines GCL, and the power lines VL and the driving voltage lines VVL are intensively located in one side direction adjacent to the display driving circuit 200, some lines may intersect each other.

For example, the gate control lines GCL transmitting the gate control signals to the gate driving circuit 210 may be arranged to intersect one or more fan-out lines FOL, which are the extension lines of the data lines DL, in the one side direction of the display panel 100 corresponding to the arrangement direction of the display driving circuit 200. For example, the driving voltage lines VVL supplying the driving voltage to the gate driving circuit 210 may be arranged to intersect one or more fan-out lines FOL, which are the extension lines of the data lines DL, in the one side direction of the display panel 100 corresponding to the arrangement direction of the display driving circuit 200. Unlike this, one or more lines of the gate control lines GCL or the driving voltage lines VVL may also be arranged to intersect at least one data line DL in the display area DA.

The sub-area SBA may include a display driving circuit 200, a display pad area DPA, and first and second touch pad areas TPA1 and TPA2.

The display driving circuit 200 may supply the gate control signals to the gate driving circuit 210 through the gate control lines GCL. Here, the gate control signal may include a plurality of clock signals having a phase different from that of the gate start signal. In addition, the display driving circuit 200 may also output driving voltages (or high potential and low potential driving voltages) for driving the gate driving circuit 210 through the driving voltage lines VVL.

In addition, the display driving circuit 200 may supply the data voltage to the data lines DL through the fan-out lines FOL. The data voltage may be supplied to the plurality of pixels SP and may determine luminance of the plurality of pixels SP. Here, a power supply unit may be built into the display driving circuit 200, and the power supply unit may also be built into a distinct main processor or the like.

The display pad area DPA, the first touch pad area TPA1, and the second touch pad area TPA2 may be located at an edge of the sub-area SBA. The display pad area DPA, the first touch pad area TPA1, and the second touch pad area TPA2 may be electrically connected to the circuit board 300 using an anisotropic conductive layer or a low-resistance and high-reliability material such as SAP.

The display pad area DPA may include a plurality of display pad portions. The plurality of display pad units may be connected to the touch driving circuit 400 and a distinct main processor through the circuit board 300. The plurality of display pad portions may be connected to the circuit board 300 to receive digital video data and supply the digital video data to the display driving circuit 200.

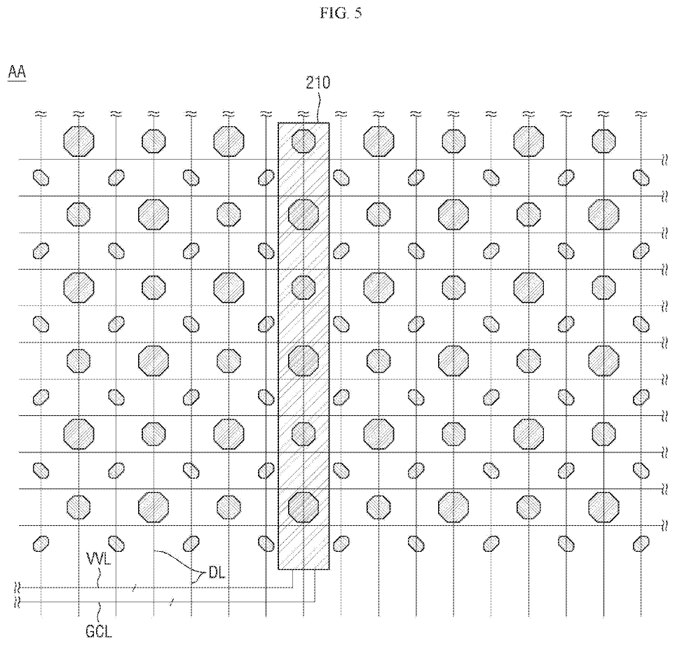

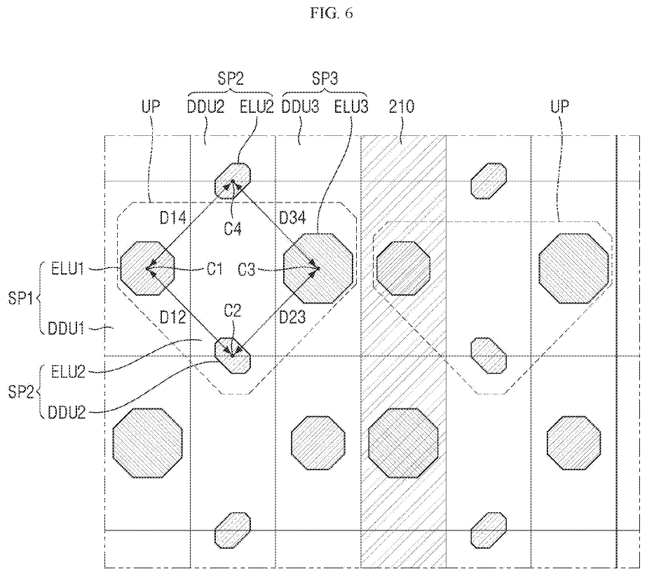

FIG. 5 is a layout view illustrating an enlarged AA area in which data lines, gate control lines, and power lines of FIG. 4 intersect. In addition, FIG. 6 is a layout view specifically illustrating an image display area illustrated in FIG. 5.

Referring to FIGS. 5 and 6, the gate driving circuit 210 is located in the display area DA, and a plurality of pixels SP each divided into first display pixels SP1, second display pixels SP2, and third display pixels SP3 are arranged on a front surface of the display area DA including the gate driving circuit 210.

The first display pixel SP1, the second display pixel SP2, and the third display pixel SP3 may be defined as one unit pixel US. Each unit pixel UP may be defined as first to third display pixels SP1, SP2, and SP3 of a minimum unit capable of displaying white. As another example, each unit pixel UP may be defined as first to fourth display pixels of a minimum unit capable of displaying white. In this case, the fourth display pixel may emit light of the same color as any one of the first to third display pixels. Unlike this, the fourth display pixel may also be formed without a color filter so as to emit white light.

Each unit pixel US may be arranged in a vertical or horizontal matrix form along the X-axis and Y-axis directions of the display area DA. In addition, each unit pixel US may also be arranged in a zigzag form. For example, each unit pixel US may also be arranged in a pentile™ matrix structure in the display area DA.

The first display pixel SP1 may include a first light emitting unit ELU1 emitting first light and a first pixel driving unit DDU1 for applying a driving current to a light emitting element of the first light emitting unit ELU1. The first light may be light in a red wavelength band. For example, a main peak wavelength of the first light may be positioned between approximately 600 nm and 750 nm.

The second display pixel SP2 may include a second light emitting unit ELU2 emitting second light and a second pixel driving unit DDU2 for applying a driving current to a light emitting element of the second light emitting unit ELU2. The second light may be light in a green wavelength band. For example, a main peak wavelength of the second light may be positioned between approximately 480 nm and 560 nm.

The third display pixel SP3 may include a third light emitting unit ELU3 emitting third light and a third pixel driving unit DDU3 for applying a driving current to a light emitting element of the third light emitting unit ELU3. The third light may be light in a blue wavelength band. For example, a main peak wavelength of the third light may be positioned between approximately 370 nm and 460 nm.

In each unit pixel US, the first pixel driving unit DDU1 and the second pixel driving unit DDU2 may be located adjacent to each other in a diagonal direction, and the first pixel driving unit DDU1 and the third pixel driving unit DDU3 may be arranged in the X-axis direction. Similarly, the second pixel driving unit DDU2 and the third pixel driving unit DDU3 may be arranged in one diagonal direction. In this case, each unit pixel US may be arranged in a zigzag form.

The first light emitting unit ELU1, the second light emitting unit ELU2, and the third light emitting unit ELU3 may have an octagonal planar shape, but are not limited thereto. The first light emitting unit ELU1, the second light emitting unit ELU2, and the third light emitting unit ELU3 may have a quadrangular planar shape such as a rhombus or a polygonal planar shape other than a quadrangle and an octagon.

Due to the arrangement position and planar shape of the first light emitting unit ELU1, the second light emitting unit ELU2, the third light emitting unit ELU3, and another adjacent second light emitting unit ELU2, a distance D12 between a center C1 of the first light emitting unit ELU1 and a center C2 of the second light emitting unit ELU2, a distance D23 between the center C2 of the second light emitting unit ELU2 and a center C3 of the third light emitting unit ELU3, a distance D34 between the center C3 of the third light emitting unit ELU3 and a center C4 of another adjacent second light emitting unit ELU2, and a distance D14 between the center C1 of the first light emitting unit ELU1 and the center C4 of another adjacent second light emitting unit ELU2 may be substantially the same.

As described above, the gate driving circuit 210 is arranged in the Y-axis direction in the display area DA, and each pixel SP may overlap on a front surface of the gate driving circuit 210. As illustrated in FIGS. 4 and 5, the gate control lines GCL are connected between the gate driving circuit 210 and the display driving circuit 200. In this case, the gate control lines GCL extend from an input end of one side surface of the gate driving circuit 210 to the sub-area SBA in which the display driving circuit 200 is arranged along the non-display area NDA of the display panel 100. In this case, depending on the arrangement position of the gate driving circuit 210 located in the display area DA, the data lines DL or the fan-out lines FOL, which are the extension lines of the data lines DL, may intersect the gate control lines GCL. In other words, the gate control lines GCL may intersect the data lines DL or may intersect the fan-out lines FOL, which are the extension lines of the data lines DL.

Similarly, the driving voltage lines VVL are connected between the gate driving circuit 210 and the display driving circuit 200 or the power supply end of the power supply unit. In this case, the driving voltage lines VVL also extend from the input end of one side surface of the gate driving circuit 210 to the sub-area SBA in which the display driving circuit 200 is arranged along the non-display area NDA of the display panel 100. Therefore, depending on the arrangement position of the gate driving circuit 210 located in the display area DA, the data lines DL or the fan-out lines FOL, which are the extension lines of the data lines DL, may intersect the driving voltage lines VVL.

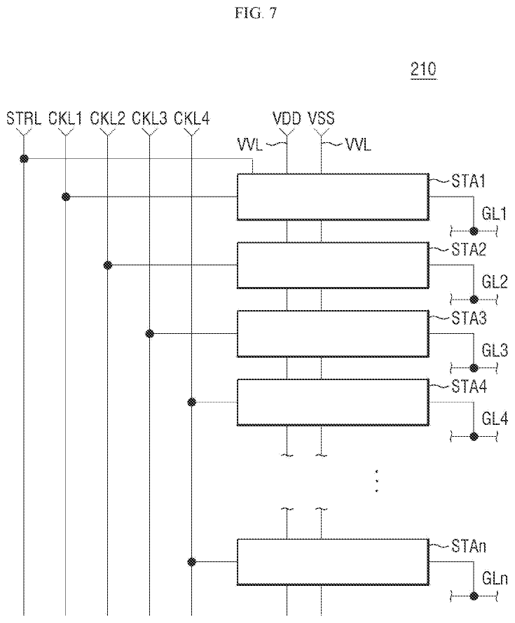

FIG. 7 is an view illustrating a gate driving circuit formed in the image display area of FIGS. 4 to 6 divided for each block.

Referring to FIG. 7, the gate driving circuit 210 located in the display area DA may include a plurality of display stages STA1, STA2, . . . , STAn (n is a positive integer).

The plurality of display stages STA1, STA2, . . . , STAn may be connected to at least one of the respective clock signal transmission lines CKL1, CKL2, CKL3, or CKL4, and may receive at least one clock signal having a different phase from the display driving circuit 200. In addition, the plurality of display stages STA1, STA2, . . . , STAn operate by receiving high and low potential driving voltages through high and low potential driving voltage lines VDD and VSS among the voltage lines VVL.

A first display stage STA1 among the plurality of display stages STA1, STA2, . . . , STAn may be connected to a gate start signal transmission line STRL, which is one of gate control lines GCL, and may receive a gate start signal from the display driving circuit 200.

The plurality of display stages STA1, STA2, . . . , STAn are sequentially (or subordinately) connected from the first display stage STA1 to the last n-th display stage STAn. Accordingly, the plurality of display stages STA1, STA2, . . . , STAn may sequentially generate the gate signals starting from the first display stage STA1, and sequentially transmit the gate signals to the first to n-th gate lines GL1 to GLn.

As an example, the first display stage STA1 generates a gate signal in response to the gate start signal and a first clock signal, and supplies the gate signal to a first gate line GL1 and a second display stage STA2 of a next stage. Subsequently, the second display stage STA2 generates a gate signal in response to the gate signal of the first display stage STA1 of the previous stage and a second clock signal, and supplies the gate signal to a second gate line GL2 and a third display stage STA3 of a next stage. In this order, the gate signals are supplied to the n-th gate line GLn until the last n-th display stage STAn. The plurality of display stages STA1, STA2, . . . , STAn may sequentially supply the gate signals to the first to n-th gate lines GL1 to GLn in units of at least one frame period.

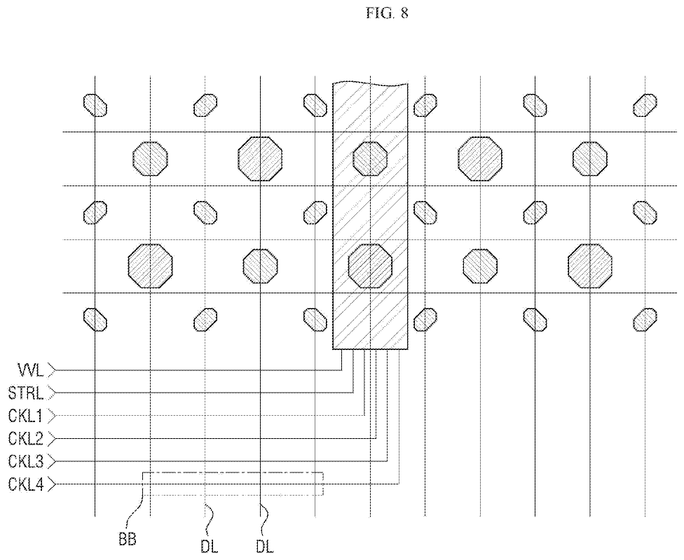

FIG. 8 is a layout view illustrating a more enlarged intersection area of the data lines, the gate control lines, and the power lines of FIG. 5.

Referring to FIG. 8, depending on the arrangement position of the gate driving circuit 210 located in the display area DA, the data lines DL or the fan-out lines FOL, which are the extension lines of the data lines DL, may intersect the gate control lines GCL.

In particular, in the display panel 100 used in a mobile display device such as a smartphone or tablet PC, because the data lines DL, and the gate control lines GCL and the voltage lines VVL are intensively located in one side direction adjacent to the display driving circuit 200, the lines are arranged to intersect each other.

The gate control lines GCL may include a gate start signal transmission line STRL and a plurality of clock signal transmission lines CKL1, CKL2, CKL3, and CKL4. In this case, the gate start signal transmission line STRL and the plurality of clock signal transmission lines CKL1, CKL2, CKL3, and CKL4 may intersect the data lines DL or may intersect the fan-out lines FOL, which are the extension lines of the data lines DL.

Depending on the arrangement position of the gate driving circuit 210 located in the display area DA, the driving voltage lines VVL may also intersect the data lines DL or may intersect the fan-out lines FOL, which are the extension lines of the data lines DL. The voltage lines VVL may include high-potential and low-potential driving voltage lines VDD and VSS. In this case, the high-potential and low-potential driving voltage lines VDD and VSS may intersect the data lines DL or may intersect the fan-out lines FOL, which are the extension lines of the data lines DL.

s the gate start signal transmission line STRL and the plurality of clock signal transmission lines CKL1, CKL2, CKL3, and CKL4 intersect the data lines DL (or the fan-out lines FOL, which are the extension lines of the data lines DL), an electromagnetic coupling phenomenon may occur in each intersecting node or intersecting area (e.g., a BB area).

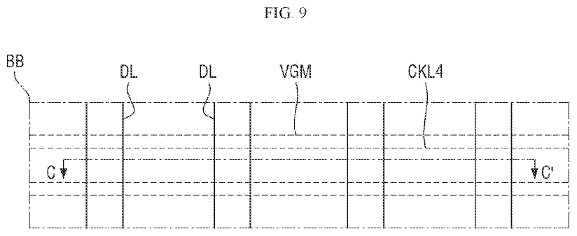

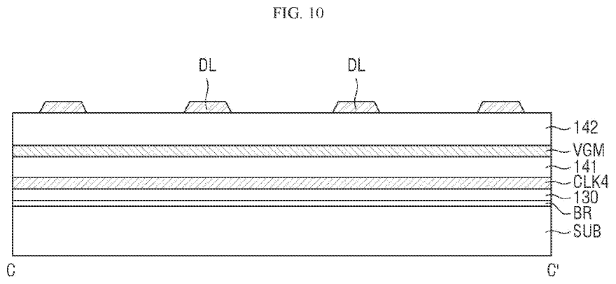

FIG. 9 is a layout view specifically illustrating a BB area in which the data lines of FIG. 8 and one gate control line intersect. In addition, FIG. 10 is a cross-sectional view illustrating a section taken along line C-C′ illustrated in FIG. 9.

Referring to FIGS. 9 and 10, an area (e.g., a BB area) in which the gate control lines GCL and at least one data line DL intersect each other may include gate control lines GCL, a first interlayer insulating layer 141, an electrostatic pattern lines VGM, a second interlayer insulating layer 142, at least one data line DL. The first interlayer insulating layer 141, the electrostatic pattern lines VGM, and the second interlayer insulating layer 142 may be included between the gate control lines GCL and the at least one data line DL.

As an example, referring to the layout and section views of the BB area of FIGS. 8 and 9 in which the fourth clock signal transmission line CKL4 and at least one data line DL intersect each other, a barrier layer BR is first formed on the substrate SUB. The barrier layer BR is a film for protecting the thin film transistor layer of the sub-pixels SP and various lines from moisture permeating through the substrate SUB, which is vulnerable to moisture permeation. The barrier layer BR may include a plurality of inorganic layers alternately stacked. For example, the barrier layer BR may be formed as a multilayer layer in which one or more inorganic layers of a silicon nitride layer, a silicon oxynitride layer, a silicon oxide layer, a titanium oxide layer, and an aluminum oxide layer are alternately stacked.

A gate insulating layer 130 for protecting active layers of the thin film transistors is formed on the barrier layer BR, and the gate control lines GCL are formed on the gate insulating layer 130. The gate control lines GCL may be formed as a single layer or multiple layers made of any one of molybdenum (Mo), aluminum (AI), chromium (Cr), gold (Au), titanium (Ti), nickel (Ni), neodymium (Nd), and copper (Cu), or an alloy thereof.

A first interlayer insulating layer 141 is formed on the gate insulating layer 130 including the gate control line GCL to cover at least one gate control line GCL. The first interlayer insulating layer 141 may be formed as a multilayer layer in which a plurality of inorganic layers are alternately stacked.

The electrostatic pattern lines VGM are patterned and formed on the first interlayer insulating layer 141 so as to overlap the gate control line GCL and cover the gate control line GCL in parallel with the first interlayer insulating layer 141 interposed therebetween. The electrostatic pattern lines VGM may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof. The electrostatic pattern lines VGM may extend to the display driving circuit 200 or a separate power supply unit.

A second interlayer insulating layer 142 covering the electrostatic pattern lines VGM is formed on the first interlayer insulating layer 141 including the electrostatic pattern lines VGM. The second interlayer insulating layer 142 may be formed as the same plurality of inorganic layers as the first interlayer insulating layer 141.

A plurality of data lines DL may be formed on the second interlayer insulating layer 142 in a direction intersecting the gate control lines GCL and the electrostatic pattern lines VGM. The plurality of data lines DL may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof.

A constant voltage of a level (e.g., a set or predetermined level) may be applied to the electrostatic pattern lines VGM formed to intersect at least one data line DL with the first interlayer insulating layer 141 interposed therebetween through the display driving circuit 200 or the separate power supply unit. Accordingly, the gate control lines GCL formed to intersect at least one data line DL with the electrostatic pattern lines VGM interposed therebetween are blocked from coupling with at least one data line DL by the electrostatic pattern lines VGM located therebetween. That is, as illustrated in FIGS. 9 and 10, the fourth clock signal transmission line CKL4 formed to intersect at least one data line DL with the electrostatic pattern lines VGM interposed therebetween are blocked from coupling with at least one data line DL by the electrostatic pattern lines VGM located therebetween.

Similarly, the driving voltage lines VVL may also be formed to intersect at least one data line DL with the electrostatic pattern line VGM interposed therebetween. That is, the electrostatic pattern lines VGM are located in the same structure in the intersecting area between the driving voltage lines VVL and the data lines DL. Accordingly, the voltage lines VVL may also be blocked from coupling with at least one data line DL by the electrostatic pattern lines VGM.

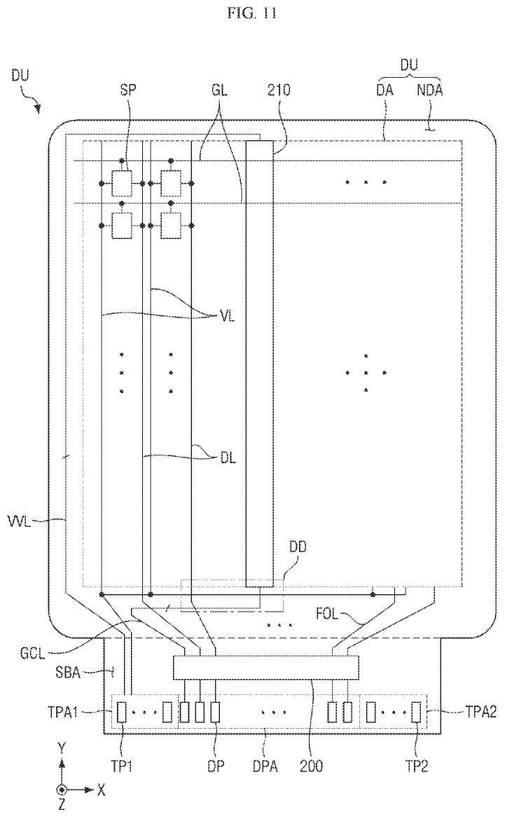

FIG. 11 is a layout view schematically illustrating a display panel according to some embodiments as illustrated in FIGS. 1 to 3.

Referring to FIG. 11, in the display module DU used in a mobile display device such as a smartphone or tablet PC, because the data lines DL and the gate control lines GCL, and the power lines VL and the driving voltage lines VVL are intensively arranged in one side direction adjacent to the display driving circuit 200, some lines may intersect each other.

In order to minimize the design in which the lines intersect, the driving voltage lines VVL may be arranged along the non-display area NDA, which is a peripheral area of the display area DA, in a form surrounding the display area DA, and may be connected to the gate driving circuit 210 so as not to overlap or intersect the gate lines GL and the data lines DL.

However, the gate control lines GCL transmitting the gate control signals to the gate driving circuit 210 may be arranged to intersect one or more fan-out lines FOL, which are the extension lines of the data lines DL, in the one side direction of the display panel 100 corresponding to the arrangement direction of the display driving circuit 200.

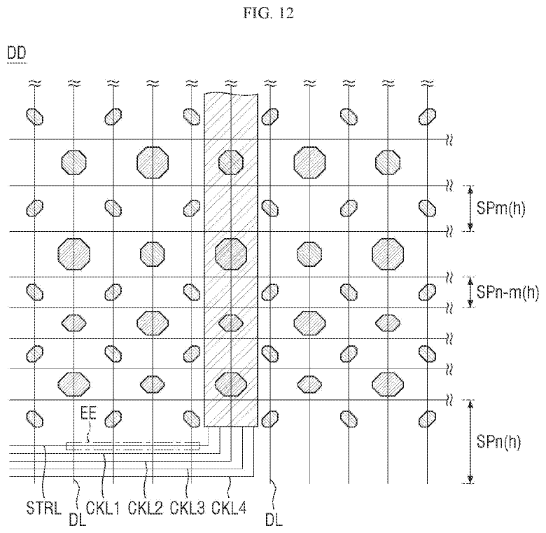

FIG. 12 is a layout view illustrating an enlarged EE area in which data lines, gate control lines, and power lines of FIG. 11 intersect.

Referring to FIG. 12, widths of the pixels SP arranged in the display area DA in at least one direction may be differently formed according to the arrangement area of the pixels SP.

As a specific example, a formation width of the pixels SP arranged in a preset first planar area among the pixels SP arranged in the display area DA in one direction may be formed as a first width SPm(h) that is a reference width. In addition, a formation width of the pixels SP arranged in a second planar area among the pixels SP arranged in the display area DA in one direction may be formed as a second width SPn-m(h) smaller than the first width SPm(h). Accordingly, a formation width of the pixels SP arranged in a third planar area among the pixels SP arranged in the display area DA in one direction may be formed as a third width SPn(h) greater than the first width SPm(h). That is, the formation width of the pixels SP arranged in the third planar area in one direction among the pixels SP arranged in the display area DA may be greater than the widths of the pixels SP formed in the first and second planar areas.

In this case, the gate control lines GCL may also be arranged to intersect at least one data line DL in the display area DA. For example, the gate control lines GCL may be arranged to intersect at least one data line DL in an arrangement area of the pixels SP located in the third planar area among the pixels SP arranged in the display area DA.

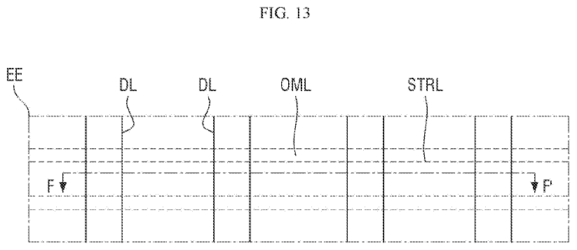

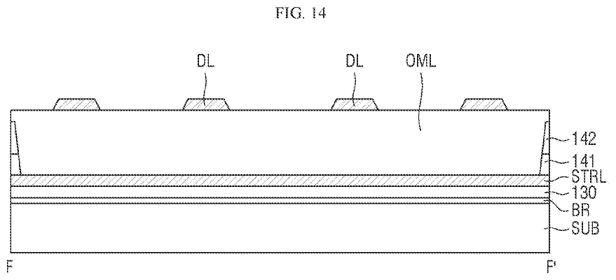

FIG. 13 is a layout view specifically illustrating an EE area in which the data lines of FIG. 12 and one gate control line intersect. In addition, FIG. 14 is a cross-sectional view illustrating a section taken along line F-F′ illustrated in FIG. 13.

Referring to FIGS. 13 and 14, an area (e.g., an EE area) in which the gate control lines GCL and at least one data line DL intersect may include an organic insulating pattern layer OML between the gate control lines GCL and at least one data line DL.

As an example, referring to the layout and section views of the EE area of FIGS. 13 and 14 in which the gate start signal transmission line STRL and at least one data line DL intersect each other, a barrier layer BR is first formed on the substrate SUB.

The barrier layer BR is a film for protecting the thin film transistor layer of the sub-pixels SP and various lines from moisture permeating through the substrate SUB, which is vulnerable to moisture permeation.

A gate insulating layer 130 for protecting active layers of the thin film transistors may be formed on the barrier layer BR, and the gate control lines GCL may be formed on the gate insulating layer 130.

A first interlayer insulating layer 141 is formed on the gate insulating layer 130 including one or more gate control lines GCL to cover the one or more gate control lines GCL. In addition, a second interlayer insulating layer 142 is formed on the first interlayer insulating layer 141. The second interlayer insulating layer 142 may be formed as the same plurality of inorganic layers as the first interlayer insulating layer 141.

Thereafter, a pattern hole having a preset size and width is formed in an intersection area predetermined to intersect one or more data lines DL among front areas of one or more gate control lines GCL. In addition, an organic insulating pattern layer OML is formed by filling an organic material in the pattern hole having the preset size and width. The organic insulating pattern layer OML includes at least one organic material such as an acryl resin, an epoxy resin, a phenolic resin, a polyamide resin, a polyimide resin, or the like.

A plurality of data lines DL are formed on a portion of the second interlayer insulating layer 142 and the organic insulating pattern layer OML in a direction intersecting the organic insulating pattern layer OML. The plurality of data lines DL may be formed to intersect the organic insulating pattern layer OML and the gate control lines GCL.

Because the organic materials of the organic insulating pattern layer OML have a smaller dielectric constant than other inorganic materials or materials of interlayer insulating layers, the gate control lines GCL formed to intersect at least one data line DL with the organic insulating pattern layer OML therebetween may be blocked from coupling with at least one data line DL by the organic insulating pattern layer OML.

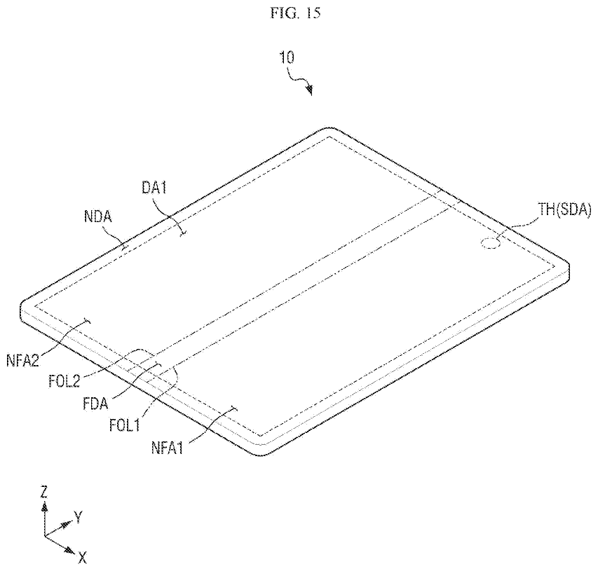

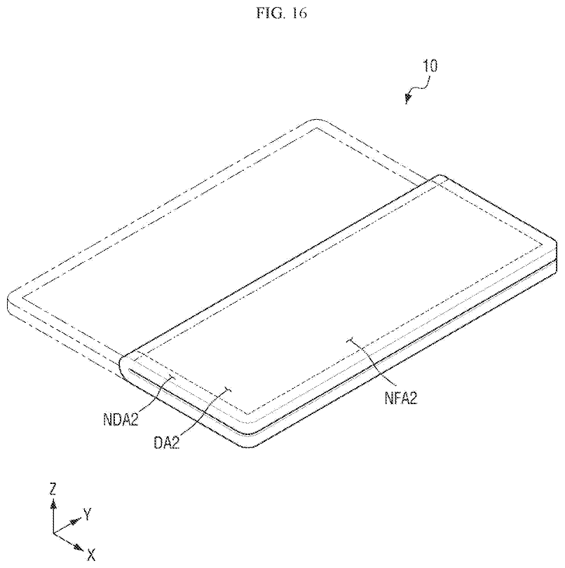

FIGS. 15 and 16 are perspective views illustrating a display device according to some embodiments of the present disclosure.

FIGS. 15 and 16 illustrate that the display device 10 is a foldable display device that is folded in the first direction (X-axis direction). The display device 10 may maintain both a folded state and an unfolded state. The display device 10 may be folded in an in-folding manner in which a front surface thereof is located on an inner side. When the display device 10 is bent or folded in the in-folding manner, the front surfaces of the display device 10 may be arranged to face each other. Alternatively, the display device 10 may be folded in an out-folding manner in which the front surface thereof is located on an outer side. When the display device 10 is bent or folded in the out-folding manner, rear surfaces of the display device 10 may be arranged to face each other.

A first non-folding area NFA1 may be located on one side, for example, a right side of a folding area FDA. A second non-folding area NFA2 may be located on the other side, for example, a left side of the folding area FDA. The touch sensing unit TSU according to some embodiments of the present specification may be formed and located on the first non-folding area NFA1 and the second non-folding area NFA2, respectively.

A first folding line FOL1 and a second folding line FOL2 may extend in the second direction (Y-axis direction), and the display device 10 may be folded in the first direction (X-axis direction). Accordingly, because a length of the display device 10 in the first direction (X-axis direction) may be reduced by about half, it may be convenient for the user to carry the display device 10.

Meanwhile, the extending direction of the first folding line FOL1 and the extending direction of the second folding line FOL2 are not limited to the second direction (Y-axis direction). For example, the first folding line FOL1 and the second folding line FOL2 may extend in the first direction (X-axis direction), and the display device 10 may be folded in the second direction (Y-axis direction). In this case, a length of the display device 10 in the second direction (the Y-axis direction) may be reduced by about half. Alternatively, the first folding line FOL1 and the second folding line FOL2 may extend in a diagonal direction between the first direction (X-axis direction) and the second direction (Y-axis direction) of the display device 10. In this case, the display device 10 may be folded in a triangular shape.

When the first folding line FOL1 and the second folding line FOL2 extend in the second direction (Y-axis direction), a length of the folding area FDA in the first direction (X-axis direction) may be shorter than a length thereof in the second direction (Y-axis direction). In addition, a length of the first non-folding area NFA1 in the first direction (X-axis direction) may be longer than the length of the folding area FDA in the first direction (X-axis direction). A length of the second non-folding area NFA2 in the first direction (X-axis direction) may be longer than the length of the folding area FDA in the first direction (X-axis direction).

A first display area DA1 may be located on the front surface of the display device 10. The first display area DA1 may overlap the folding area FDA, the first non-folding area NFA1, and the second non-folding area NFA2. Therefore, when the display device 10 is unfolded, an image may be displayed in a front direction in the folding area FDA, the first non-folding area NFA1, and the second non-folding area NFA2 of the display device 10.

A second display area DA2 may be located on the rear surface of the display device 10. The second display area DA2 may overlap the second non-folding area NFA2. Therefore, when the display device 10 is folded, an image may be displayed in the front direction in the second non-folding area NFA2 of the display device 10.

FIGS. 15 and 16 illustrate that a through hole TH in which a camera SDA is formed is located in the first non-folding area NFA1, but embodiments according to the present disclosure are not limited thereto. The through hole TH or the camera SDA may be located in the second non-folding area NFA2 or the folding area FDA.

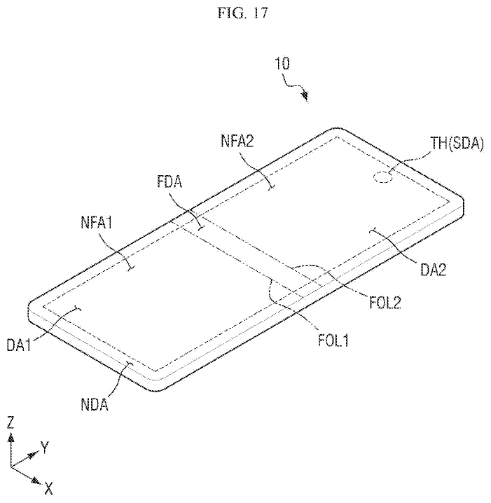

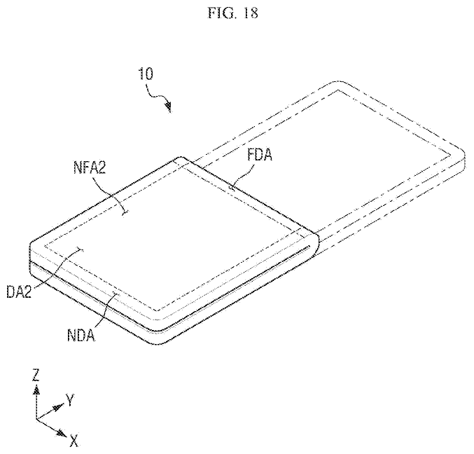

FIGS. 17 and 18 are perspective views illustrating a display device according to some embodiments of the present disclosure.

FIGS. 17 and 18 illustrate that the display device 10 is a foldable display device that is folded in the second direction (Y-axis direction). The display device 10 may maintain both a folded state and an unfolded state. The display device 10 may be folded in an in-folding manner in which a front surface thereof is located on an inner side. When the display device 10 is bent or folded in the in-folding manner, the front surfaces of the display device 10 may be arranged to face each other. Alternatively, the display device 10 may be folded in an out-folding manner in which the front surface thereof is located on an outer side. When the display device 10 is bent or folded in the out-folding manner, rear surfaces of the display device 10 may be arranged to face each other.

The display device 10 may include a folding area FDA, a first non-folding area NFA1, and a second non-folding area NFA2. The folding area FDA may be an area in which the display device 10 is folded, and the first non-folding area NFA1 and the second non-folding area NFA2 may be areas in which the display device 10 is not folded. The first non-folding area NFA1 may be located on one side, for example, a lower side of the folding area FDA. The second non-folding area NFA2 may be located on the other side, for example, an upper side of the folding area FDA.

The touch sensing unit TSU according to some embodiments of the present

specification may be formed and located on the first non-folding area NFA1 and the second non-folding area NFA2, respectively.

On the other hand, the folding area FDA may be an area bent with a curvature (e.g., a set or predetermined curvature) at the first folding line FOL1 and the second folding line FOL2. Therefore, the first folding line FOL1 may be a boundary between the folding area FDA and the first non-folding area NFA1, and the second folding line FOL2 may be a boundary between the folding area FDA and the second non-folding area NFA2.

As illustrated in FIGS. 17 and 18, the first folding line FOL1 and the second folding line FOL2 may extend in the first direction (X-axis direction), and the display device 10 may be folded in the second direction (Y-axis direction). Accordingly, because a length of the display device 10 in the second direction (Y-axis direction) may be reduced by about half, it may be convenient for a user to carry the display device 10.

Meanwhile, the extending direction of the first folding line FOL1 and the extending direction of the second folding line FOL2 are not limited to the first direction (X-axis direction). For example, the first folding line FOL1 and the second folding line FOL2 may extend in the second direction (Y-axis direction), and the display device 10 may be folded in the first direction (X-axis direction). In this case, a length of the display device 10 in the first direction (the X-axis direction) may be reduced by about half. Alternatively, the first folding line FOL1 and the second folding line FOL2 may extend in a diagonal direction between the first direction (X-axis direction) and the second direction (Y-axis direction) of the display device 10. In this case, the display device 10 may be folded in a triangular shape.

When the first folding line FOL1 and the second folding line FOL2 extend in the first direction (X-axis direction) as illustrated in FIGS. 17 and 18, a length of the folding area FDA in the second direction (Y-axis direction) may be shorter than a length thereof in the first direction (X-axis direction). In addition, a length of the first non-folding area NFA1 in the second direction (Y-axis direction) may be longer than the length of the folding area FDA in the second direction (Y-axis direction). In addition, a length of the second non-folding area NFA2 in the second direction (Y-axis direction) may be longer than the length of the folding area FDA in the second direction (Y-axis direction).

A first display area DA1 may be located on the front surface of the display device 10. The first display area DA1 may overlap the folding area FDA, the first non-folding area NFA1, and the second non-folding area NFA2. Therefore, when the display device 10 is unfolded, an image may be displayed in a front direction in the folding area FDA, the first non-folding area NFA1, and the second non-folding area NFA2 of the display device 10.

A second display area DA2 may be located on the rear surface of the display device 10. The second display area DA2 may overlap the second non-folding area NFA2. Therefore, when the display device 10 is folded, an image may be displayed in the front direction in the second non-folding area NFA2 of the display device 10.

FIGS. 17 and 18 illustrate that a through hole TH in which a camera SDA is located is arranged in the second non-folding area NFA2, but embodiments according to the present disclosure are not limited thereto. The through hole TH may be located in the first non-folding area NFA1 or the folding area FDA.

In concluding the detailed description, those skilled in the art will appreciate that many variations and modifications can be made to the disclosed embodiments without substantially departing from spirit and scope of embodiments according to the present disclosure. Therefore, the disclosed embodiments of the disclosure are used in a generic and descriptive sense only and not for purposes of limitation.

What is claimed is:

1. A display device comprising:
display pixels formed in an image display area of a display panel;
a gate driving circuit formed in the image display area and configured to supply gate signals to the display pixels;
a display driving circuit configured to supply a data voltage to data lines in the image display area through fan-out lines arranged in a non-display area of the display panel and configured to supply gate control signals to the gate driving circuit through gate control lines arranged in the non-display area; and
driving voltage lines arranged in the non-display area and configured to to supply driving voltages to the gate driving circuit,
wherein at least one gate control line of the gate control lines intersects one or more fan-out lines of the fan-out lines in one side direction of the image display area corresponding to an arrangement direction of the display driving circuit.

2. The display device of claim 1, wherein the at least one gate control line of the gate control lines intersects one or more data lines of the data lines in the image display area in one side direction corresponding to the arrangement direction of the display driving circuit.

3. The display device of claim 2, wherein the gate control lines include a gate start signal transmission line and a plurality of clock signal transmission lines, and
the one or more data lines intersect one or more signal transmission lines of the gate start signal transmission line and the plurality of clock signal transmission lines, or intersect the one or more fan-out lines.

4. The display device of claim 2, wherein a formation width of display pixels arranged in a preset first plane area among the display pixels arranged in the image display area in one direction is formed as a first width that is a reference width,
a formation width of display pixels arranged in a preset second plane area among the display pixels arranged in the image display area in one direction is formed as a second smaller than the first width, and
a formation width of display pixels arranged in a preset third plane area among the display pixels arranged in the image display area in one direction is formed as a third greater than the first width.

5. The display device of claim 4, wherein the one or more data lines intersect at least one gate control line of the gate control lines in an arrangement area of the display pixels in the third plane of the image display area.

6. The display device of claim 2, wherein in an intersection area in which the one or more gate control lines and the one or more fan-out lines or the data lines intersect,
electrostatic pattern lines to which a constant voltage is applied are located between the one or more gate control lines and the one or more fan-out lines that intersect each other, or between the one or more gate control lines and the data lines that intersect each other.

7. The display device of claim 6, wherein the intersection area in which the at least one gate control line and the one or more fan-out lines or the data lines intersect includes:
a first interlayer insulating layer covering the one or more gate control lines;
the electrostatic pattern lines on the first interlayer insulating layer to overlap in parallel with the one or more gate control lines; and
a second interlayer insulating layer formed to cover the first interlayer insulating layer including the electrostatic pattern lines, and
the one or more fan-out lines or the data lines intersect the at least one gate control line with the second interlayer insulating layer interposed therebetween.

8. The display device of claim 2, wherein in an intersection area in which the one or more gate control lines and the one or more fan-out lines or the data lines intersect,
an organic insulating pattern layer is formed between the one or more gate control lines and the one or more fan-out lines or the data line that intersect each other.

9. The display device of claim 8, wherein the organic insulating pattern layer covering the at least one gate control line is formed in the intersection area in which the one or more gate control lines and the one or more fan-out lines or the data lines intersect, and
the one or more fan-out lines or the data lines intersect the at least one gate control line with the organic insulating pattern layer interposed therebetween.

10. The display device of claim 1, wherein at least one driving voltage line of the driving voltage lines intersect the one or more fan-out lines in one side direction of the image display area corresponding to an arrangement direction of the display driving circuit.

11. The display device of claim 10, wherein the at least one driving voltage line of the driving voltage lines intersect one or more data lines of the data lines in the image display area in one side direction corresponding to the arrangement direction of the display driving circuit.

12. The display device of claim 11, wherein in an intersection area in which the at least driving voltage line and the one or more fan-out lines or the data lines intersect,
electrostatic pattern lines to which a constant voltage is applied are between the at least one driving voltage line and the one or more fan-out lines or the data lines that intersect each other.

13. The display device of claim 12, wherein the intersection area in which the at least driving voltage line and the one or more fan-out lines or the data lines intersect includes:
a first interlayer insulating layer covering the at least one driving voltage line;
the electrostatic pattern lines on the first interlayer insulating layer to overlap the at least one driving voltage line; and
a second interlayer insulating layer formed to cover the first interlayer insulating layer including the at least one driving voltage line, and
the one or more fan-out lines or the data lines intersect the at least one driving voltage line with the second interlayer insulating layer interposed therebetween.

14. The display device of claim 11, wherein in an intersection area in which the at least driving voltage line and the one or more fan-out lines or the data lines intersect,
an organic insulating pattern layer is formed between the at least one driving voltage line and the one or more fan-out lines or the data line that intersect each other.

15. The display device of claim 14, wherein in the intersection area in which the at least driving voltage line and the one or more fan-out lines or the data lines intersect,
the organic insulating pattern layer covers the at least one driving voltage line, and
the one or more fan-out lines or the data lines intersect the at least one driving voltage line with the organic insulating pattern layer interposed therebetween.

16. A display device comprising:
a display panel including an image display area and a non-display area;
display pixels in the image display area;
a gate driving circuit formed in the image display area and configured to supply gate signals to the display pixels;
a display driving circuit configured to supply a data voltage to data lines in the image display area through fan-out lines in the non-display area and configured to supply gate control signals to the gate driving circuit through gate control lines in the non-display area; and
driving voltage lines in the non-display area and configured to supply driving voltages to the gate driving circuit,
wherein at least one gate control line of the gate control lines intersect one or more fan-out lines of the fan-out lines in one side direction of the image display area corresponding to an arrangement direction of the display driving circuit, and
at least one driving voltage line of the driving voltage lines intersect the one or more vvvv lines of the fan-out lines in one side direction of the image display area corresponding to an arrangement direction of the display driving circuit.

17. The display device of claim 16, wherein the at least one gate control line of the gate control lines intersect one or more data lines of the data lines in the image display area in one side direction corresponding to the arrangement direction of the display driving circuit.

18. The display device of claim 17, wherein the gate control lines include a gate start signal transmission line and a plurality of clock signal transmission lines, and
one or more signal transmission lines of the gate start signal transmission line and the plurality of clock signal transmission lines intersect the one or more data lines or intersect the one or more fan-out lines.

19. The display device of claim 16, wherein the at least one driving voltage line of the driving voltage lines intersect one or more data lines of the data lines in the image display area in one side direction corresponding to the arrangement direction of the display driving circuit.

20. The display device of claim 19, wherein in an intersection area in which the at least driving voltage line and the one or more fan-out lines or the data lines intersect,
electrostatic pattern lines to which a constant voltage is applied are between the at least one driving voltage line and the one or more fan-out lines or the data lines that intersect each other.
